(19) United States
(12) Patent Application Publication
(10) Pub. No.: US 2016/0180940 A1
(43) Pub. Date: Jun. 23, 2016

(54) SEMICONDUCTOR DEVICE

(71) Applicant: SK hynix Inc., Gyeonggi-do (KR)

(72) Inventor: Yong Hwan HONG, Gyeonggi-do (KR)

(21) Appl. No.: 14/713,717

(22) Filed: May 15, 2015

(30) Foreign Application Priority Data
Dec. 19, 2014 (KR) 10-2014-0184874

(51) Int. Cl. G11C 16/14; G11C 16/24; G11C 16/26

(52) U.S. Cl. CPC G11C 16/14; G11C 16/26; G11C 16/24

(57) ABSTRACT

A semiconductor device is provided. The semiconductor device includes a memory block including memory cells connected to word lines, and an operation circuit configured to perform a program operation on the memory cells. The operation circuit performs the program operation to respectively store a plurality of data in memory cells of different word lines and different columns.

### CROSS-REFERENCE TO RELATED APPLICATION

The present application claims priority to Korean patent application number 10-2014-0184874, filed on Dec. 19, 2014, the entire disclosure of which is herein incorporated by reference in its entirety.

### BACKGROUND

1. Field of Invention

The present invention relates to a semiconductor device.

More specifically, the present invention relates to a semiconductor device capable of storing data.

2. Description of Related Art

A memory block of a semiconductor device includes memory cells connected to word lines. In order to read data from memory cells connected to word lines different from each other, a read operation is performed on every word line. That is, read operations are performed as many as the number of the word lines, and thus a lot of time is required to complete the read operation.

### SUMMARY

The present invention is directed to a semiconductor device capable of improving an operation speed.

One aspect of the present invention provides a semiconductor device including a memory block including memory cells connected to word lines, and an operation circuit configured to perform a program operation on the memory cells. The operation circuit performs the program operation to respectively store a plurality of data in memory cells of different word lines and different columns.

Another aspect of the present invention provides semiconductor device including a memory block including memory cells connected to word lines, a plurality of data being stored in memory cells of different word lines and different columns; and an operation circuit configured to perform a read operation on the memory cells. The operation circuit is configured to simultaneously read the data stored in the memory cells of the different word lines and the different columns during the read operation.

Another aspect of the present invention provides a semiconductor device including a memory cell area, word lines extending in the main memory cell area and in the spare memory cell area, first bit lines extending in the main memory cell area, second bit lines extending in the spare memory cell area, main memory cells provided in the main memory cell area and including non-operation information, first spare memory cells provided in the spare memory cell area and including operation information, and second spare memory cells provided in the spare memory cell area and do not include the operation information, wherein the first spare memory cells are coupled to the word lines different from each other, wherein the first spare memory cells are coupled to the second bit lines different from each other.

### BRIEF DESCRIPTION OF THE DRAWINGS

FIG. 1 is a block diagram illustrating a semiconductor device according to an embodiment of the present invention;

FIG. 2 is a circuit diagram illustrating a memory block according to the embodiment of the present invention;

FIGS. 3A to 3C are views illustrating a memory block according to another embodiment of the present invention;

FIG. 4 is a view illustrating a method of operating a semiconductor device according to an embodiment of the present invention;

FIGS. 5 and 6 are flow charts illustrating methods of operating semiconductor devices according to embodiments of the present invention;

FIG. 7 is a block diagram simply illustrating a memory system according to an embodiment of the present invention;

FIG. 8 is a block diagram simply illustrating a fusion memory device or a fusion memory system configured to perform a program operation according to an embodiments of the present invention; and

FIG. 9 is a block diagram briefly illustrating a computing system including a flash memory device according to an embodiment of the present invention.

### DETAILED DESCRIPTION

Hereinafter, the present invention will be described. In the drawings, the thicknesses of layers and regions are expressed for convenience of the descriptions, and may be exaggerated with respect to an actual physical thickness. In the descriptions of the present invention, a well-known structure may be omitted for conciseness.

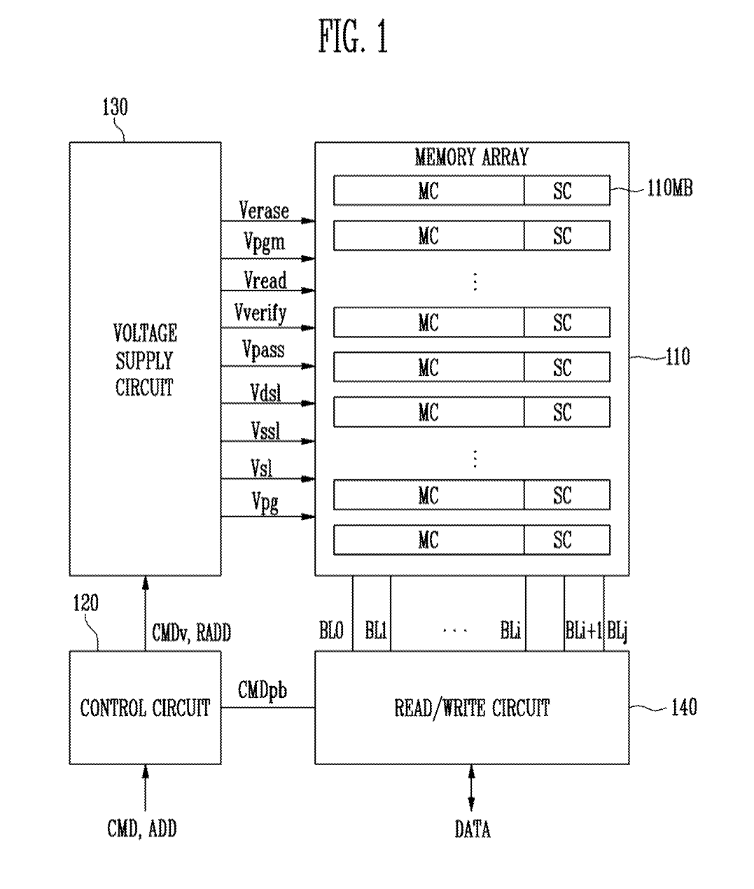

FIG. 1 is a block diagram illustrating a semiconductor device according to an embodiment of the present invention.

Referring to FIG. 1, the semiconductor device includes a memory array 110 and operation circuits 120 to 140. The memory array 110 includes a plurality of memory blocks 100MB. Each of the memory blocks 100MB includes a plurality of memory strings. Each of the memory strings includes a plurality of memory cells. For example, in a flash memory device, the memory block may include a flash memory cell. The memory cell may include a floating gate formed of polysilicon and a charge storage layer formed of a nitride layer.

In particular, the memory blocks 100MB may include memory strings connected to bit lines and connected to a common source line. The memory strings are arranged in parallel to each other. The memory strings may be formed on a semiconductor substrate in a 2-dimensional structure or a 3-dimensional structure. A structure of the memory block will be described below in more detail.

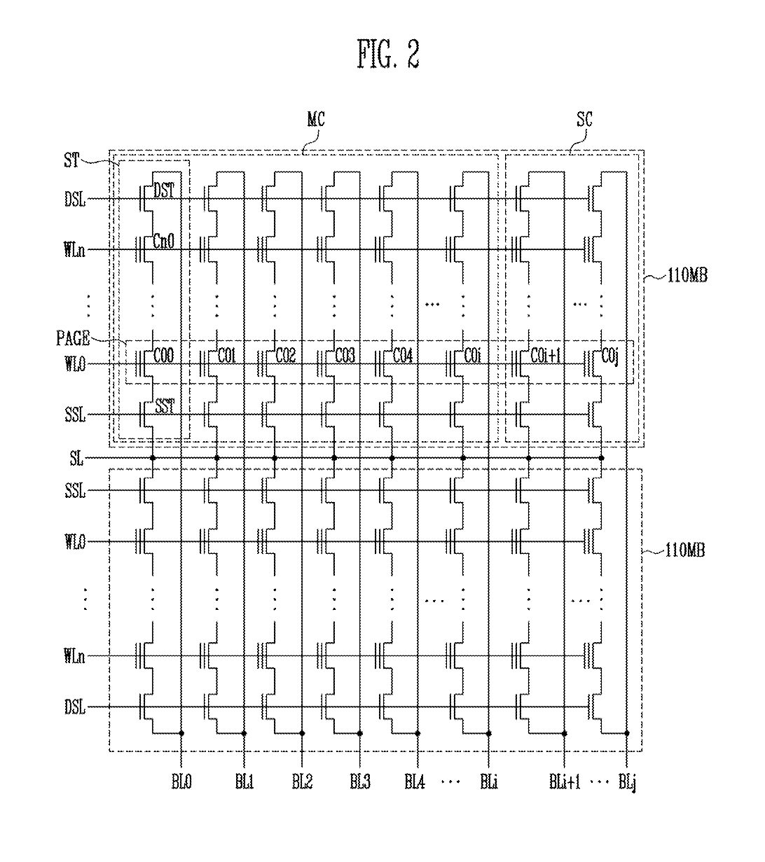

FIG. 2 is a circuit diagram illustrating a memory block according to the embodiment of the present invention.

Referring to FIG. 2, each of the memory blocks includes a plurality of memory strings ST connected between bit lines BL0 to BLj and a common source line SL. That is, the memory strings ST are connected to corresponding bit lines BL0 to BLj, respectively, and commonly connected to the common source line SL. Each of the memory strings ST includes a source select transistor SST having a source connected to the common source line SL, a cell string including a plurality of memory cells C00 to Cn0 that are connected to each other in series, and a drain select transistor DST having a drain connected to a bit line BL0. Memory cells C00 to Cn0 included in the cell string are connected to each other in series between the select transistors SST and DST. A gate of the source select transistor SST is connected to a source select line SSL, and gates of the memory cells C00 to Cn0 are connected to word lines WL0 to WLn (n is an integer), respectively. A gate of the drain select transistor DST is connected to a drain select line DSL.

The drain select transistor′ DST controls a connection or disconnection between the cell string and the bit line. The source select transistor SST controls a connection or disconnection between the cell string and the common source line SL.

In a NAND flash memory device, memory cells included in a given memory cell block are physically or functionally divided into plurality of pages. In an embodiment, the memory cells included in a given memory cell block may be physically divided into an even page and an odd page. For example, the memory cells C00 to C0j connected to the word line WL0 configure one physical page PAGE. The even numbered memory cells C00, C02, C04, and C0j−1 (j is an integer) connected to the word line WL0 may configure an even page. The odd numbered memory cells C01, C03, C05, and C0j may configure an odd page. The above pages (i.e., the even page and the odd page) may serve as a basic unit of a program operation or a read operation.

Meanwhile, the memory block 100MB may be divided into a main memory cell area MC to store first data (also referred to as “non-operation information”) inputted from the outside and a spare memory cell area SC to store second data (also referred to as “operation information”) related to operation information. The main memory cell area MC may include memory cells C00 to C0i (i is an integer). The memory cells C00 to C0i located in the main memory cell area MC is referred to as main memory cells. The memory cell area SC may include memory cells C0i+1 to Coj. The memory cells C0i+1 to Coj located in the spare memory cell area SC is referred to as spare memory cells. The main memory cells and the spare memory cells may be in the same structure.

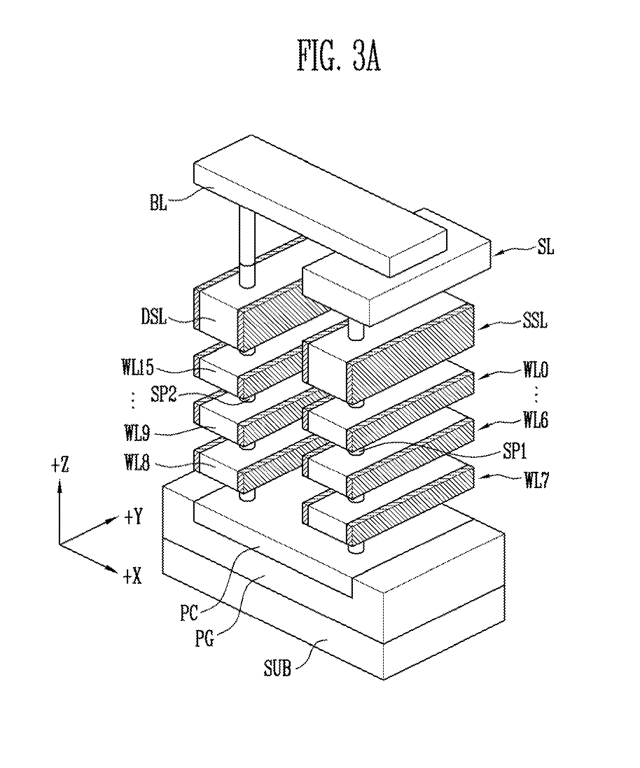

FIGS. 3A to 3C are views illustrating a memory block according to another embodiment of the present invention.

Referring to FIGS. 3A and 3B, a pipe gate PG is formed on a semiconductor substrate SUB having a recessed portion, and a pipe channel layer PC is formed in the recessed portion of the pipe gate PG. A plurality of vertical channel layers SP1 and SP2 are formed on the pipe channel layer PC. An upper portion of a first vertical channel layer SP1 among the pair of the vertical channel layers is connected to a common source line SL, and an upper portion of a second vertical channel layer SP2 is connected to a bit line BL. The vertical channel layers SP1 and SP2 may be formed of polysilicon.

A plurality of first conductive layers DSL, WL15 to WL8 are formed at different levels of the second vertical channel layer SP2 and surround the second vertical channel layer SP2. Also, a plurality of second conductive layers SSL, WL0 to WL7 are formed at different levels of the first vertical channel layer SP1 and surround the first vertical channel layer SP1. A multilayer (not shown) including a charge storage layer is formed (i) between the vertical channel layer SP1 and conductive layers SSL, WL0 to WL7, (ii) between the vertical channel layer SP2 and conductive layers DSL, WL15 to WL8, and (iii) between the pipe channel layer PC and the pipe gate PG.

An uppermost conductive layer which surrounds the second vertical channel layer SP2 may be the drain select line DSL, and conductive layers under the drain select line DSL may be word lines WL15 to WL8. An uppermost conductive layer which surrounds the first vertical channel layer SP1 may be the source select line SSL, and conductive layers under the source select line SSL may be the word lines WL0 to WL7. Some of the conductive layers WL0 to WL15 may be dummy word lines (not shown).

That is, the first conductive layers SSL, WL0 to WL7 and the second conductive layers DSL, WL15 to WL8 are each stacked in different areas of the semiconductor substrate. The first vertical channel layer SP1, which passes through the first conductive layers SSL, WL0 to WL7, is vertically connected between the source line SL and the pipe channel layer PC. The second vertical channel layer SP2, which passes through the second conductive layers DSL, WL15 to WL8, is vertically connected between the bit line BL and the pipe channel layer PC.

A drain select transistor DST is formed between the drain select line DSL and the second vertical channel layer SP2. The main cell transistors C15 to C8 are formed at between the word lines WL15 to WL8 and the second vertical channel layer SP2, respectively. A source select transistor SST is formed between the source select line SSL and the first vertical channel layer SP1. The main cell transistors C0 to C7 are formed between the word lines WL0 to WL7 and the first vertical channel layer SP1, respectively.

According to the above structure, a unit memory string includes (i) the drain select transistor DST and the main cell transistors C15 to C8 which are connected in series between the bit line BL and the pipe channel layer PC through the first vertical channel layer SP1 and (ii) the source select transistor SST and the main cell transistors C0 to C7 connected in series between the common source line SL and the pipe channel layer PC through the second vertical channel layer SP2. In an embodiment, a dummy cell transistor (not shown) may further be connected between the select transistor DST or SST and the main cell transistor C15 or C0, and a dummy cell transistor (not shown) may further be provided between the main cell transistor C8 or C7 and the pipe transistor PT.

The source select transistor SST and the main cell transistors C0 to C7 connected between the common source line SL and the pipe transistor PT may configure a first vertical memory string. The drain select transistor DST and the main cell transistors C15 to C8 connected between the bit line BL and the pipe transistor PT may configure a second vertical memory string.

Referring to FIG. 3C, the memory block 100MB includes a plurality of memory strings ST commonly connected to the same bit line. The memory string ST having a U-shape includes a first vertical memory string and a second vertical memory string. The first vertical memory string includes the source select transistor SST and the memory cells C0 to C7, which are vertically connected in series to each other between the common source line SL and the pipe transistor PT. The second vertical memory string includes the memory cells C8 to C15 and the drain select transistor DST, which are vertically connected in series to each other between the bit line BL and the pipe transistor PT.

The source select transistor SST is controlled by voltages applied to source select lines SSL0 and SSL1. The memory cells C0 to C7 are controlled by voltages applied to stacked word lines WL0 to WL7. The drain select transistor DST is controlled by voltages applied to drain select lines DSL1 to DSL4. The memory cells C8 to C15 are controlled by voltages applied to stacked word lines WL8 to WL15.

When a memory block 100MB is selected, the pipe transistor PT connected to a pair of memory cells C7 and C8 disposed at a center of the memory string having the U-shape performs an operation of connecting the first channel layer SP1 to the second channel layer SP2.

In a memory block in a 2-dimensional structure, a single memory string is connected to a single bit line and drain select transistors of a memory block are controlled by one drain select line. In a memory block 100MB in the 3-dimensional structure, a plurality of the memory strings ST are commonly connected to a single bit line BL. In the same memory block 100MB, the number of the memory strings ST commonly connected to the same bit line BL and controlled by the same word lines may vary depending on a device design.

Under the structure where the plurality of memory strings are connected to the one bit line BL in parallel, in order to selectively connect the bit line BL to the respective memory strings ST, drain select transistors DST are provided between the bit line BL and the respective memory strings ST and independently controlled by select voltages applied to drain select lines DSL1 to DSL4.

In the memory block 100MB, the memory cells C0 to C7 of the first vertical memory string SST and C0 to C7, which are vertically connected to each other, and the memory cells C8 to C15 of the second vertical memory string C8 to C15 and DST, which are vertically connected to each other, are respectively controlled by operating voltages applied to the stacked word lines WL0 to WL7 and the stacked word lines WL8 to WL15. The word lines WL0 to WL15 are classified by a memory block unit.

The drain select lines DSL1 to DSL4, the source select lines SSL1 to SSL4 and the word lines WL0 to WL15 are local lines of the memory block 100MB. In particular, the source select lines SSL1 to SSL2 and the word lines WL0 to WL7 may be local lines of the first vertical memory string. Likewise, the drain select lines DSL1 to DSL4 and the word lines WL8 to WL15 may be local lines of the second vertical memory string. In the memory block 100MB, pipe gates PG of pipe transistors PT may be connected to each other.

Meanwhile, in the memory block 100MB, memory cells which are connected to different bit lines and share a drain select line (for example, DSL4) constitute a single page PAGE. The memory block 100MB may serve as a basic unit of an erase loop, and the page PAGE may serve as a basic unit of a program operation and a read operation.

As shown in FIG. 2, a given memory block 100MB may be divided into two blocks, i.e., the main memory cell area MC and the spare memory cell area SC. Among the memory cells (e.g., C00-C0j) commonly coupled to the same word line (e.g., WL0), i number of memory cells (e.g., C00 to C0i) that are located in the main memory cell area MC may serve as main memory cells. The memory cells (e.g., C0i+1 to C0j) located in the spare memory cell area SC may serve as spare memory cells. The main memory cells (e.g., C00 to C0i) are connected to first bit lines (e.g., BL0 to BLi). The spare memory cells (e.g., C0i+1 to C0j) are connected to second bit lines (e.g., BLi+1 to BLj).

Referring again to FIGS. 1 and 3B, the operation circuits 120 to 140 are configured to perform a program loop, an erase loop, and a read operation on memory cells (e.g., C0) connected to a selected word line (for example, WL0). The program loop includes a program operation and a verification operation, and the erase loop includes an erase operation and a verification operation. The operation circuits 120 to 140 may perform a program operation (or a post program operation) which adjusts an erase level in which threshold voltages of memory cells are distributed after the erase loop.

In order to perform the program loop, the erase loop, and the read operation, the operation circuits 120 to 140 are configured to selectively output operating voltages to the local lines SSL, WL0 to WLn, PG, and DSL and the common source line SL of the selected memory block, control precharge/discharge of the bit lines BL, or sense current flows (or voltage variations) of the bit lines BL.

In a NAND flash memory device, the operation circuits include a control circuit 120, a voltage supply circuit 130, and a read/write circuit 140. Each of the above structures will be described in detail below.

The control circuit 120 generates operating voltages Verase, Vpgm, Vread, Vverify, Vpass, Vdsl, Vssl, Vsl, and Vpg to perform the program loop, the erase loop, and the read operation at desired levels in response to a command signal CMD input from the outside, and controls the voltage supply circuit 130. The operating voltages Verase, Vpgm, Vread, Vverify, Vpass, Vdsl, Vssl, Vsl, and Vpg are applied to local lines SSL, WL0˜WL15, PG, and DSL of the selected memory block and the common source line SL. As described above, the control circuit 120 may output a voltage control signal CMDv and a row address signal RADD to the voltage supply circuit 130. Also, in order to perform the program loop, the erase loop, and the read operation, the control circuit 120 controls precharge/discharge of the bit lines BL based on data to be stored in memory cells or controls the read/write circuit 140 to sense current flows (or voltage variations) of the bit lines BL during the read operation or the verification operation. The control circuit 120 may output an operation control signal CMDpb to the read/write circuit 140.

The voltage supply circuit 130 generates required operating voltages Verase, Vpgm, Vread, Vverify, Vpass, Vdsl, Vssl, Vsl, and Vpg based on the program loop, the erase loop, and the read operation on the memory cells based on the voltage control signal CMDv of the control circuit 120. Here, the operating voltages Verase, Vpgm, Vread, Vverify, Vpass, Vdsl, Vssl, Vsl, and Vpg may include an erase voltage Verase, a program voltage Vpgm, a read voltage Vread, a pass voltage Vpass, select voltages Vdsl and Vssl, a common source voltage Vsl, a pipe gate voltage Vpg, and/or the like. Also, the voltage supply circuit 130 outputs the operating voltages Verase, Vpgm, Vread, Vverify, Vpass, Vdsl, Vssl, Vsl, and Vpg to the local lines SSL, WL0 to WLn, PG, and DSL of the selected memory block and the common source line SL in response to the row address signal RADD of the control circuit 120.

The read/write circuit 140 may include a plurality of page buffers (not shown) respectively connected to the memory array 110 through the bit lines BL. In particular, the page buffers may be connected to the bit lines BL, respectively. That is, one page buffer may be connected to one bit line. During the program operation, the page buffers selectively precharge the bit lines BL based on the operation control signal CMDpb of the control circuit 120 and data DATA to be stored in the memory cells. During the program verification operation or the read operation, based on the operation control signal CMDpb of the control circuit 120, the voltage variations or the current flows of the bit lines BL are sensed after the bit lines BL are precharged, and then, the data read from the memory cell may be latched.

The operation circuits 120 to 140 including the above described structures may perform the program operation, and thus, a plurality of data are respectively stored in memory cells of different word lines and different columns. Also, the operation circuits 120 to 140 maintain an erase state in other memory cells in the same column as the memory cell in which the data is stored. In particular, the operation circuits 120 to 140 may perform a program operation to respectively store data related to operation information in the spare memory cells of different word lines and different columns. That is, the operation circuits 120 to 140 store the data related to the operation information in the word lines in the spare memory cells respectively connected to the word lines, and perform the program operation, and thus, the spare memory cells which store the data are disposed in different column areas. Also, the other spare memory cells in the same column as the spare memory cell in which the data is stored, is maintained in the erase state by the operation circuits 120 to 140.

Meanwhile, the operation circuits 120 to 140 perform a program operation, and thus, data input from the outside is stored in the main memory cell of the selected word line when the data related to the operation information is stored in the spare memory cell of the selected word line.

After the data is stored, the operation circuits 120 to 140 perform a read operation, and thus, the data stored in the memory cells of the different word lines and the different columns are simultaneously read. For the above described, the operation circuits 120 to 140 may apply the same read voltage Vread to the word lines WL0 to WL15 during the read operation. In particular, when the data related to the operation information is read from the spare memory cells respectively connected to the word lines WL0 to WL15 the operation circuits 120 to 140 may apply the read voltage Vread to the word lines WL0 to WL15.

The operation circuits 120 to 140 may perform the read operation on the main memory cells after the read operation on the spare memory cells is performed. The operation circuits 120 to 140 may perform the read operation on the main memory cells based on an operation condition set by the data read from the spare memory cells. The operation circuits 120 to 140 may perform the read operation on the spare memory cells while bit lines of the main memory cells are discharged. Also, the operation circuits 120 to 140 may perform a read operation on the main memory cells while bit lines of the spare memory cells are discharged.

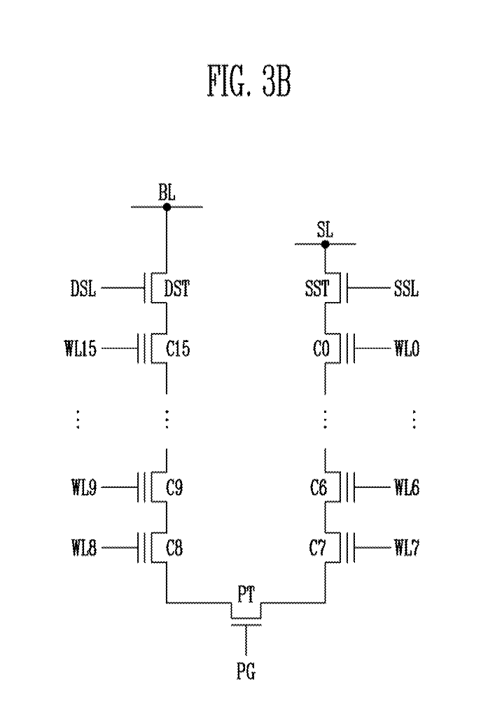

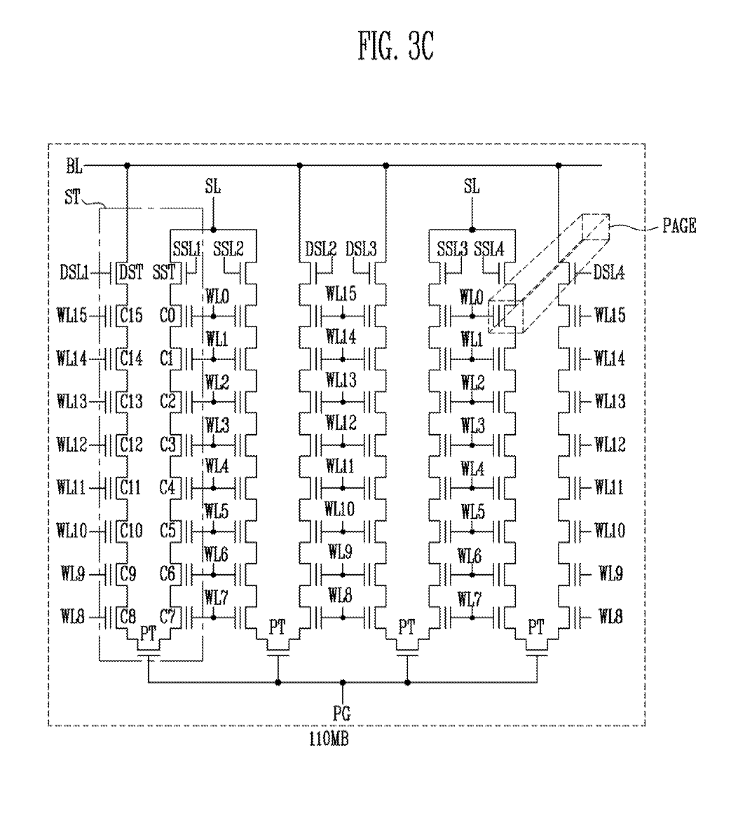

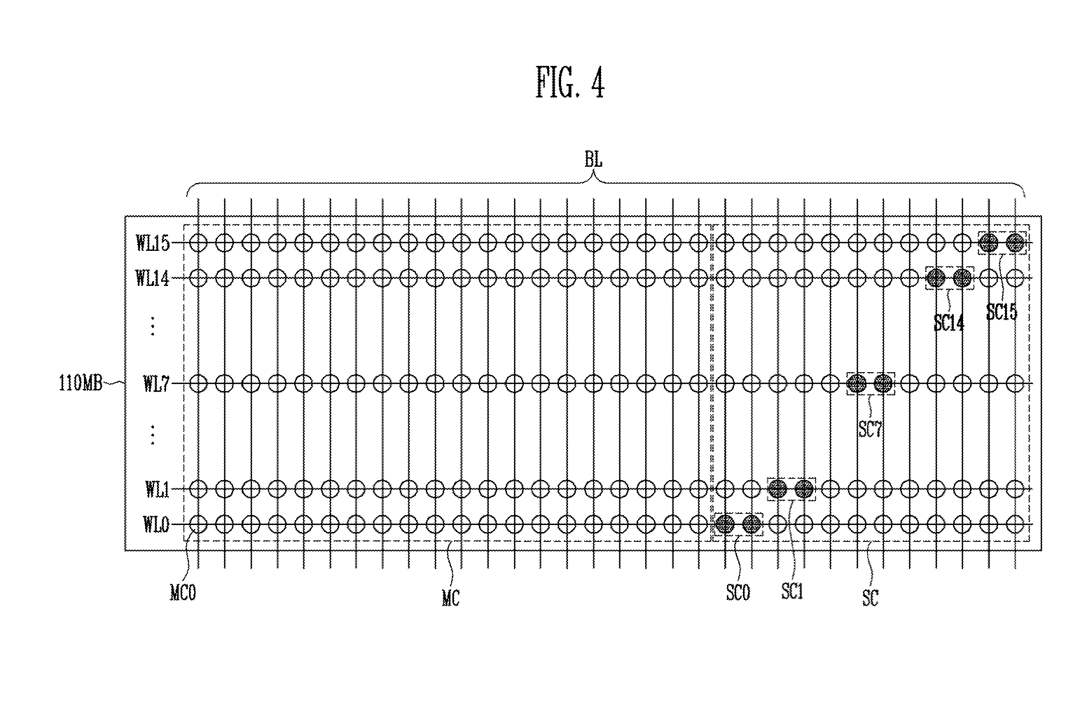

Hereinafter, a method of driving a semiconductor device will be described in more detail. FIG. 4 is a view illustrating a method of operating a semiconductor device according to an embodiment of the present invention. FIGS. 5 and 6 are flow charts illustrating methods of operating semiconductor devices according to embodiments of the present invention.

First, program operation of the memory block 100MB will be described, Referring to FIGS. 4 and 5, in S510, first data to be stored in main memory cells MC0 of a memory block 100MB is input from the outside. Here, second data to be stored in spare memory cells SC0 to SC15 may be input from the outside or generated by operation circuits 120 to 140. The second data is used when setting operation condition of each word line. The second data may be stored in a spare memory cell of a corresponding word line. For example, the second data for the first word line WL0 is stored in a selected spare memory cell SC0 coupled to the first word line WL0.

In S520, the operation circuits 120 to 140 (shown in FIG. 1) select a first word line WL0′ to store data, and select a spare memory cell SC0 of a first column in the spare memory cell area SC. Selection of the spare memory cell SC0 may be made by selecting one of bit lines coupled to the spare memory cell area SC.

In S530, the operation circuits perforin a program loop to store the first data in the main memory cells MC0 and store the second data in the spare memory cells SC0. The program loop includes a program operation and a program verification operation, and is well known in the art, and thus, any detailed descriptions will be omitted.

When the program loop is performed, the operation circuits store the second data only in the spare memory cell SC0 of a column selected from the spare memory cell area SC, and maintain an erase state in spare memory cells of the remaining columns.

In S540, the operation circuits determine whether a word line on which the program loop is performed is a last word line. When the word line on which the program loop is performed is not the last word line, in S550, the operation circuits select a next word line WL1 and select a spare memory cell SC1 of a next column.

Then, the operation circuits perform S530 and S540. When it is determined that a program loop of a last word line WL15 is completed in S540 an operation for storing data is terminated.

According to the above operations, the second data respectively stored in the spare memory cells SC0 to SC15 of different word lines and different columns in the spare memory cell area SC. That is, the spare memory cells SC0 to SC15 in which the second data is stored are disposed in different columns.

Hereinafter, read operation of the memory block 100MB in which data is stored through the above described method will be described.

Referring to FIGS. 4 and 6, in S610, the operation circuits 120 to 140 perform the read operation to read the second data related to the operation condition of the spare memory cells SC0 to SC15. According to the method described in FIG. 5, since the first and second data are stored in the memory block 100MB, the data is respectively stored in the memory cells of the different word lines and the different columns. That in the spare memory cell area SC, the second data is stored in the spare memory cells SC0 to SC15 of the different word lines and the different columns.

The operation circuits may perform the read operation, and thus, the second data stored in the spare memory cells SC0 to SC15 of the different word lines and the different columns is simultaneously read. A detailed description will be described below.

In S601, the operation circuits precharge bit lines. Here, the operation circuits may precharge only the bit lines BL connected to the spare memory cells SC0 to SC15, and maintain a discharge state in the bit lines BL connected to the main memory cells MC0.

In S603, the operation circuits apply a read voltage (Vread shown in FIG. 1) to all of the word lines WL0 to WL15. In columns of the spare memory cell area SC, since the remaining spare memory cells except the spare memory cells SC0 to SC15 are all in the erase state, the bit lines BL of the spare memory cell area SC maintain a precharge state or are discharged based on threshold voltages of the spare memory cells SC0 to SC15.

In S605, the operation circuits sense voltage states of the bit lines BL of the spare memory cell area SC, and latch the second data related to the operation condition based on the sensed result. Although the spare memory cells SC0 to SC15 are connected to different word lines WL0 to WL15, the second data may be read from the spare memory cells SC0 to SC15 in one read operation.

Also, the operation circuits set conditions of the read operation on the main memory cells MC0 based on the second data read from the spare memory cells SC0 to SC15.

In S620, the operation circuits perform the read operation on the main memory cells MC0 based on a condition set by the second data. The read operation may be sequentially performed from the first word line WL0 to the last word line WL15 based on a well-known method. Here, the operation circuits may precharge only the bit lines BL of the main cell area MC, and perform the read operation on the main memory cells while the bit lines BL in the spare memory cell area SC are discharged.

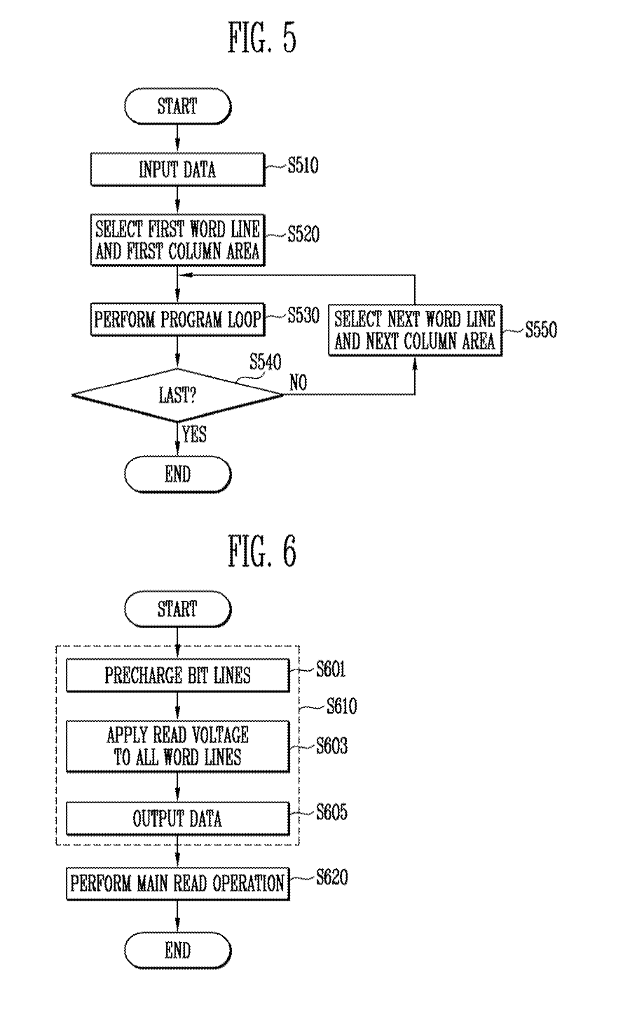

FIG. 7 is a block diagram simply illustrating a memory system according to an embodiment of the present invention.

Referring to FIG. 7, a memory system 700 according to the embodiment of the present invention includes a nonvolatile memory (NVM) device 720 and a memory controller 710.

The NVM device 720 may correspond to the semiconductor device shown in FIGS. 1 to 6. The memory controller 710 may be configured to control the NVM device 720. The NVM device 720 may be integrated with the memory controller 710, and used for a memory card or a semiconductor disk device such as a solid state disk (SSD). An SRAM 711 is used as an operational memory of a central processing unit (CPU) 712. A host interface 713 includes a data exchange protocol of a host Host connected to the memory system 700. An error correcting block (ECC) 714 detects and corrects an error in the data read from a cell area of the NVM device 720. A memory interface 715 interfaces with the NVM device 720 of the present invention. The CPU 712 performs overall control operations for data exchange of the memory controller 710.

Although not shown in FIG. 7, the memory system 700 according to the embodiment may further include a ROM (not shown) configured to store code data for interfacing with the host Host, and/or the like. The NVM device 720 may be provided as a multi-chip package having a plurality of flash memory chips. The memory system 700 according to the embodiment of the present invention may be provided to a highly reliable storage medium having improved operation characteristics. In particular, the flash memory device according to the embodiment of the present invention may be included in a memory system such as a semiconductor disk device (an SSD) which has been actively studied recently. In this case, the memory controller 710 may be configured to communicate with the outside (for example, the host Host) through at least one of various interface protocols such as a USB, an MMC, a PCI-E, an SATA, a PATA, an SCSI, an ESDI, an IDE, etc.

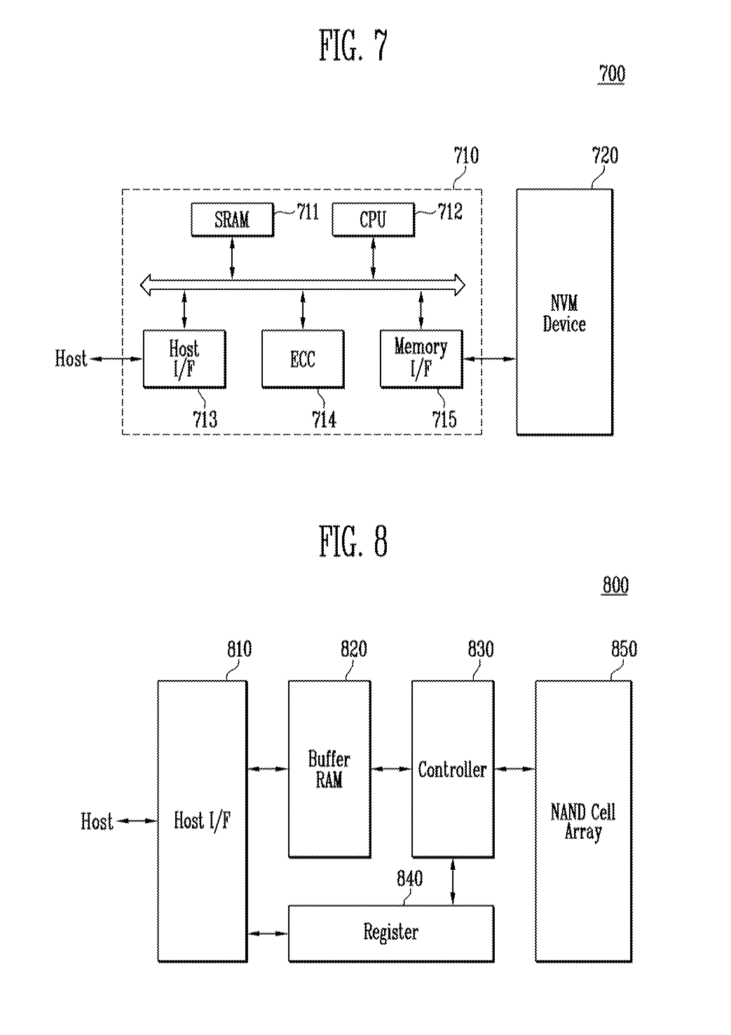

FIG. 8 is a block diagram simply illustrating a fusion memory device or a fusion memory system configured to perform a program operation according to the above-described embodiments of the present invention. For example, technical characteristics of the present invention described in FIGS. 1 to 6 may be applied to an OneNAND flash memory device 800 as a fusion memory device.

The OneNAND flash memory device 800 includes a host interface 810 configured to exchange overall information with devices using different protocols, a buffer RAM 820 which includes a code configured to drive the memory device or temporarily store data, a controller 830 configured to control a read operation, a program operation, and all states in response to a control signal and a command provided from the outside, a register 840 configured to store data such as the command and an address, a configuration for defining a system operation environment inside the memory device, and the like, and a NAND flash cell array 850 which includes an operation circuit having a nonvolatile memory cell and a page buffer. The OneNAND flash memory device 800 programs data in a general method in response to a write request from the host Host.

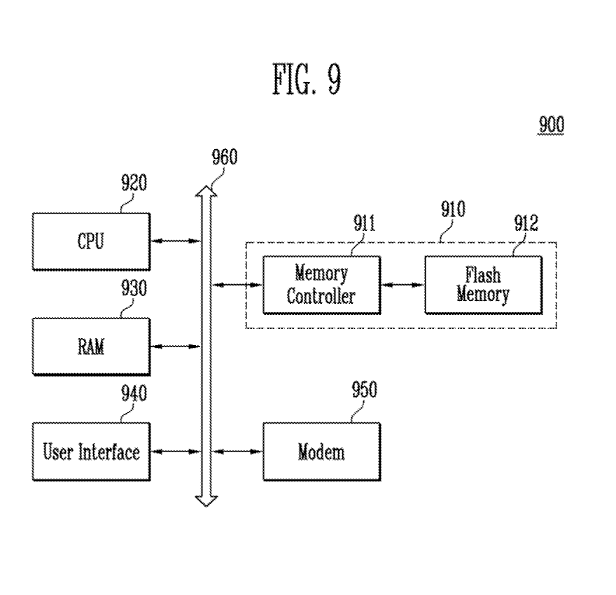

FIG. 9 is a block diagram briefly illustrating a computing system including a flash memory device 912 according to an embodiment of the present invention.

The computing system 900 according to the embodiment of the present invention includes a CPU 920, a RAM 930, a user interface 940, a modem 950 such as a baseband chipset, and a memory system 910, which are electrically connected to a system bus 960. When the computing system 900 is a mobile device, a battery (not shown) configured to supply an operating voltage to the computing system 900 may be additionally provided. Although not shown in FIG. 9, in the computing system 900 according to the embodiment of the present invention, an application chipset, a camera image processor (CIS), a mobile DRAM and/or the like may be further provided. The memory system 910, for example, may be included in a solid state drive/disk (SSD) using the nonvolatile memory device described in FIGS. 1 to 6 to store data. In another embodiment, the memory system 910 may be a fusion flash memory (for example, the OneNAND flash memory).

According to the semiconductor device according to the embodiment of the present invention, an operation speed may be improved.

Although the present invention is explained with reference to the exemplary embodiments, it will be apparent to those skilled in the art that various modifications can be made to the above-described exemplary embodiments of the present invention without departing from the spirit or scope of the invention. Here, the essential technical scope of the present invention is disclosed in the appended claims, and it is intended that the present invention covers all such modifications provided they come within the scope of the claims and their equivalents.

What is claimed is:

1. A semiconductor device, comprising:
a memory block including memory cells connected to word lines; and
an operation circuit configured to perform a program operation on the memory cells,
wherein the operation circuit performs the program operation to respectively store a plurality of data in memory cells of different word lines and different columns.

2. The semiconductor device of claim 1, wherein the operation circuit maintains remaining memory cells of a column in an erase state, in which a selected memory cell stores data, among the plurality of data, and the remaining memory cells do not store the data.

3. The semiconductor device of claim 1, wherein the memory cells connected to the word lines comprise main memory cells configured to store first data input from the outside, among the plurality of data, and spare memory cells configured to store second data related to operation information, among the plurality of data.

4. The semiconductor device of claim 3, wherein the operation circuit performs the program operation to store the second data in spare memory cells of the different word lines and the different columns.

5. The semiconductor device of claim 3, wherein the second data is stored in spare memory cells of a selected word line, and
wherein the first data is stored in main memory cells of the selected word line.

6. The semiconductor device of claim 3, wherein the operation circuit maintains remaining memory cells of a column in an erase state, in which a selected memory cell stores data, among the plurality of data, and the remaining memory cells do not store the data.

7. A semiconductor device comprising:
a memory block including memory cells connected to word lines, a plurality of data being stored in selected memory cells of different word lines and different columns; and
an operation circuit configured to perform a read operation on the selected memory cells,
wherein the operation circuit is configured to simultaneously read the data stored in the selected memory cells of the different word lines and the different columns during the read operation.

8. The semiconductor device of claim 7, wherein remaining memory cells of a column, wherein remaining memory cells of a column in which a selected memory cell stores data, among the plurality of data, and the remaining memory cells do not store the data are maintained in an erase state.

9. The semiconductor device of claim 7, wherein the operation circuit is configured to apply the same read voltage to the word lines during the read operation.

10. The semiconductor device of claim 7, wherein the memory cells connected to the word lines comprise main memory cells configured to store first data input from the outside, among the plurality of data, and spare memory cells configured to store second data related to operation information among the plurality of data.

11. The semiconductor device of claim 10, wherein the second data is respectively stored in spare memory cells of the different word lines and the different columns.

12. The semiconductor device of claim 10, wherein remaining memory cells of a column in which a selected memory cell stores data, among the plurality of data, and the remaining memory cells do not store the data are maintained in an erase state.

13. The semiconductor device of claim 10, wherein a read operation on the spare memory cells is performed and the operation circuit is configured to perform a read operation on the main memory cells.

14. The semiconductor device of claim 13, wherein the operation circuit is configured to discharge bit lines of the main memory cells during the read operation on the spare memory cells.

15. The semiconductor device of claim 13, wherein the operation circuit is configured to discharge bit lines of the spare memory cells during the read operation on the main memory cells.

16. The semiconductor device of claim 13, wherein the operation circuit is configured to perform the read operation on the main memory cells based on a condition set by the second data read from the spare memory cells.

17. A semiconductor device, comprising:
a memory block including a main memory cell area and a spare memory cell area;
word lines extending in the main memory cell area and in the spare memory cell area;
first bit lines extending in the main memory cell area;
second bit lines extending in the spare memory cell area;
main memory cells provided in the main memory cell area and including non-operation information;
first spare memory cells provided in the spare memory cell area and including operation information; and
second spare memory cells provided in the spare memory cell area and do not include the operation information;
wherein the first spare memory cells are coupled to the word lines different from each other,
wherein the first spare memory cells are coupled to the second bit lines different from each other.

18. The semiconductor device of claim 17, wherein the number of the word lines is L (L is an integer),
wherein the number of the first bit lines is M (M is an integer),
wherein the number of the second bit lines is N (N is an integer),
wherein the number of the main memory cells is L*M,
wherein the number of the first spare memory cells is L or more,
wherein the number of the second spare memory cells is (L*N−L) or less.

19. The semiconductor device of claim 17,
wherein the operation information included in the first spare memory cells set read operation conditions of the word lines to which the first spare memory cells are coupled, respectively.

20. The semiconductor device of claim 17, further including a reading circuit reading out the operation information and the non-operation information from the memory block,
wherein the reading circuit includes first and second circuits,
wherein the first circuit (i) applies a first read voltage to the word lines, (ii) applies a first discharge voltage to the first bit lines, and (applies a first precharge voltage to the second bit lines to read out the operation information from the first spare memory cells, and
wherein the second circuit (i) applies a second read voltage to the word lines, (ii) applies a second precharge voltage to the first bit lines, and (iii) applies a second discharge voltage to the second bit lines to read out the non-operation information from the main memory cells.
